(19) United States
(12) Patent Application Publication
(10) Pub. No.: US 2014/0000707 A1
(43) Pub. Date: Jan. 2, 2014

(54) DOUBLE-LAYER FILM OF A PHOTOVOLTAIC MODULE

(71) Applicants: Stephane Bizet, Barc (FR); Samuel Devisme, Rouen (FR); Thomas Fine, Lyon (FR); Dominique Jousset, Bougival (FR); Gregory O'Brien, Chester, PA (US); Amy Lefebvre, Pottstown, PA (US)

(72) Inventors: Stephane Bizet, Barc (FR); Samuel Devisme, Rouen (FR); Thomas Fine, Lyon (FR); Dominique Jousset, Bougival (FR); Gregory O'Brien, Chester, PA (US); Amy Lefebvre, Pottstown, PA (US)

(73) Assignee: ARKEMA FRANCE, Colombes (FR)

(21) Appl. No.: 13/984,549

(22) PCT Filed: Jan. 12, 2012
(86) PCT No.: PCT/FR2012/050082

§ 371 Date: Sep. 19, 2013

(30) Foreign Application Priority Data
Feb. 11, 2011 (FR) 1151111

(51) Int. Cl. H01L 31/0203

(52) U.S. Cl. CPC H01L 31/0203
USPC 136/259; 428/474.7; 428/421

(57) ABSTRACT

A double-layer thermoplastic film of a photovoltaic module, including two layers, one forms the encapsulator and the other forms the backsheet, wherein: a) the encapsulator is a layer including at least one polyolefin containing a polyethylene selected from a homopolymer of ethylene or a copolymer comprising at least 50 mol % of ethylene and at least one comonomer and between 0% and 100% of a polyamide grafted polymer comprising a polyolefin trunk that represents between 50 mass % and 95 mass % of the polyamide grafted polymer containing a radical of at least one unsaturated monomer (X) and at least one polyamide graft that represents between 5 mass % and 50 mass % of said polyamide grafted polymer; and b) the backsheet comprises a layer formed from a polyamide grafted polymer that is identical to that of the encapsulator except that it has a flow temperature higher than 160° C.

### FIELD OF THE INVENTION

One subject of the invention is a double-layer (encapsulant-backsheet) film for photovoltaic modules having optimum properties for this application. The present invention also relates to a photovoltaic module comprising, besides the aforesaid double-layer film and an optional supplementary layer, an adjacent layer forming a “frontsheet”, more generally the three successive layers denoted by “frontsheet”, encapsulant and “backsheet”.

Global warming, linked to the greenhouse gases released by fossil fuels, has led to the development of alternative energy solutions which do not emit such gases during their operation, such as for example photovoltaic modules. A photovoltaic module comprises a “photovoltaic cell”, this cell being capable of converting light energy into electricity.

There are many types of photovoltaic panel structures.

In FIG. 1, a conventional photovoltaic cell has been represented; this photovoltaic cell 10 comprises cells 12, one cell containing a photovoltaic sensor 14, generally based on silicon that is treated in order to obtain photoelectric properties, in contact with electron collectors 16 placed above (upper collectors) and below (lower collectors) the photovoltaic sensor. The upper collectors 16 of one cell are connected to the lower collectors 16 of another cell 12 by conducting bars 18, generally consisting of an alloy of metals. All these cells are connected to one another, in series and/or in parallel, in order to form the photovoltaic cell 10. When the photovoltaic cell 10 is placed under a light source, it delivers a continuous electric current, which may be recovered at the terminals 19 of the cell 10.

With reference to FIG. 2, the photovoltaic module 20 comprises the photovoltaic cell 10 from FIG. 1 encased in an “encapsulant”, the latter being composed of an upper portion and a lower portion. An upper protective layer 24 (known under the term “frontsheet”, used hereinafter) and a protective layer on the back of the module (known under the term “backsheet”, also used hereinafter) 26 are positioned on either side of the encapsulated cell.

The impact and moisture protection of the photovoltaic cell 10 is provided by the upper protective layer 24, generally made of glass.

The backsheet 26 contributes to the moisture protection of the photovoltaic module 20 and to the electrical insulation of the cells 12 to prevent any contact with the outside environment.

The encapsulant 22 must perfectly adopt the shape of the space existing between the photovoltaic cell 10 and the protective layers 24 and 26 in order to avoid the presence of air, which would limit the efficiency of the photovoltaic module. The encapsulant 22 must also prevent contact of the cells 12 with water and oxygen from the air, in order to limit the corrosion thereof. The upper portion of the encapsulant 22 is between the cell 10 and the upper protective layer 24. The lower portion of the encapsulant 22 is between the cell 10 and the backsheet 26.

In the presence of solar radiation, a temperature rise is created inside the solar module and temperatures of 80° C. (or more) may be achieved, which requires that the layers be perfectly bonded to one another throughout the life cycle of the module.

### PRIOR ART

Currently, in order to manufacture a photovoltaic module, the three layers to be assembled together, namely successively the “frontsheet”, the encapsulant and the “backsheet”, are produced separately. These layers are combined during the module manufacturing step, which is usually carried out by a vacuum lamination process.

In order to promote the adhesion between the layers, in particular between the backsheet and the encapsulant, use is made either of “chemical” techniques by adding a binder between the two layers or specific adhesion promoters, or of physical surface treatment techniques such as a corona or plasma treatment.

These two methods are not satisfactory since they consist, apart from a not inconsiderable additional cost (material, specific tools, implementation time), of an operation that is sometimes complex for a result that is often disappointing. In addition, the physical surface treatments are not stable over time and require storage and handling precautions to be taken.

Furthermore, the encapsulant is a material which must enable the incorporation of the photovoltaic cells at the time of assembling the three layers (frontsheet, encapsulant and backsheet) of the module. Two main types of encapsulants exist: thermoplastic encapsulants and cross-linkable encapsulants. In both cases, the encapsulant is melted during the lamination step of the photovoltaic module in order to encase the active layers.

Besides the handling of numerous films, this type of photovoltaic module manufacturing process has drawbacks linked to the shrinkage of the encapsulant film. Indeed, it is known that encapsulant films exhibit a shrinkage which may reach up to 10% in most cases, or even sometimes up to 50%. This shrinkage may lead to defects in the photovoltaic module such as air bubbles, creases, blisters, covering defects at the edges or breakages of the connectors between cells. All these defects are the cause of rejects during the manufacture of the modules or may reduce their service life and their efficiency. Specifically, air bubbles in the encapsulant may be the cause of corrosion points that considerably reduce the life cycle and also the efficiency of the photovoltaic module. The shrinkage phenomenon gives rise, within the encapsulant, to stresses that may break one or more photovoltaic cells and cause, in particular due to the fact that the latter are mounted in series, an irremediable deterioration of the operating properties of the photovoltaic module.

In order to limit these problems, the manufacturers of encapsulant films are obliged to use an extrusion process comprising a post-curing step in order to limit this shrinkage at the expense of the extrusion speed and therefore of the cost of the films.

### BRIEF DESCRIPTION OF THE INVENTION

The present invention intends to solve the problems of the encapsulants of photovoltaic modules of the prior art by providing a double-layer film produced in a single operation and comprising the encapsulant layer and the backsheet layer.

It has been observed by the applicant, after various experiments and manipulations, that a particular structure could alone exhibit optimum results making it possible to overcome the problems linked, on the one hand, to the manufacturing process of a module and, on the other hand, to the intrinsic defects of the combination of the encapsulant-backsheet layers.

Thus, the present invention relates to a double-layer thermoplastic film for a photovoltaic module, comprising two layers, of which one layer forms the encapsulant and the other layer forms the backsheet, the encapsulant-backsheet assembly having a thickness of greater than 100 μm (micrometer), characterized in that:

a) the encapsulant consists of a layer comprising:
from 0% to 100% of one or more polyolefins containing a polyethylene chosen from a homopolymer of ethylene or a copolymer comprising at least 50 mol % of ethylene and of one or more comonomers,
from 0% to 100% of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
   the polyamide graft is attached to the polyolefin backbone by the residue of the unsaturated monomer (X) comprising a function capable of reacting via a condensation reaction with a polyamide having at least one amine end group and/or at least one carboxylic acid end group,
   the residue of the unsaturated monomer (X) is attached to the backbone by grafting or copolymerization,
   the polyolefin backbone and the polyamide graft being chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone;
      b) the backsheet comprises a layer formed from a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end group and/or at least one carboxylic acid end group,
the residue of the unsaturated monomer (X) is attached to the backbone by grafting or copolymerization,
the polyolefin backbone and the polyamide graft being chosen so that said polyamide graft polymer has a flow temperature of greater than 160° C., this flow temperature being defined as the highest temperature among the melting temperatures and glass transition temperatures of the polyamide graft and of the polyolefin backbone.

Other advantageous characteristics of the invention are specified below:
the aforesaid graft polymers of the encapsulant and of the backsheet are nanostructured;
the number-average molar mass of the aforesaid polyamide grafts of the aforesaid graft polymers of the encapsulant and of the backsheet is within the range extending from 1000 to 5000 g/mol, preferably within the range extending from 2000 to 3000 g·mol⁻¹;
for the aforesaid graft polymers of the encapsulant and of the backsheet, the number of monomers (X) attached to the polyolefin backbone is greater than or equal to 1.3 and/or less than or equal to 10;
the at least one polyamide graft of the graft polymer of the encapsulant comprises at least one copolyamide;
the polyolefin backbone of the graft polymer of the encapsulant does not have a melting temperature or has a melting temperature below 110° C.;
the homopolymer of ethylene of the polyolefin of the encapsulant is a linear low-density polyethylene (LLDPE), advantageously an LLDPE obtained by metallocene catalysis;
the copolymer of polyethylene of the polyolefin of the encapsulant is chosen from an ethylene/α-olefin copolymer, the density of which is between 0.865 and 0.91 (ASTM D 1505 standard), or an ethylene/alkyl (meth)acrylates/anhydride copolymer;
the backsheet also comprises a layer formed from a fluoropolymer consisting of a homopolymer of vinylidene difluoride or a copolymer of vinylidene difluoride and at least one other fluoromonomer;
the layer forming a backsheet comprises fillers chosen from silica, alumina, calcium carbonates, carbon nanotubes, glass fibers or else modified or unmodified clays, which are mixed on the nanometer scale;
the layer forming an encapsulant comprises adhesion promoters consisting of a non-polymeric ingredient, of organic, crystalline or mineral nature, and more preferably of semi-mineral, semi-organic nature;
the backsheet consists of two layers only and the encapsulant consists of a single layer.

The invention relates to the use of the film as described above in a photovoltaic module.

Finally, the invention also relates to a photovoltaic module having at least one layer forming an encapsulant comprising a photovoltaic cell capable of generating electrical energy and one layer forming a backsheet, these two layers constituting the film as described above.

### DESCRIPTION OF THE APPENDED FIGURES

The description which follows is given solely by way of illustration and nonlimitingly with reference to the appended figures, in which:

FIG. 1, already described, represents an example of a photovoltaic cell, the parts (a) and (b) being ¾ views, part (a) showing a cell before connection and part (b) a view after connection of two cells; part (c) is a top view of a complete photovoltaic cell.

FIG. 2, already described, represents a cross section of a photovoltaic module, the “conventional” photovoltaic sensor of which is encapsulated by an upper encapsulant film and a lower encapsulant film.

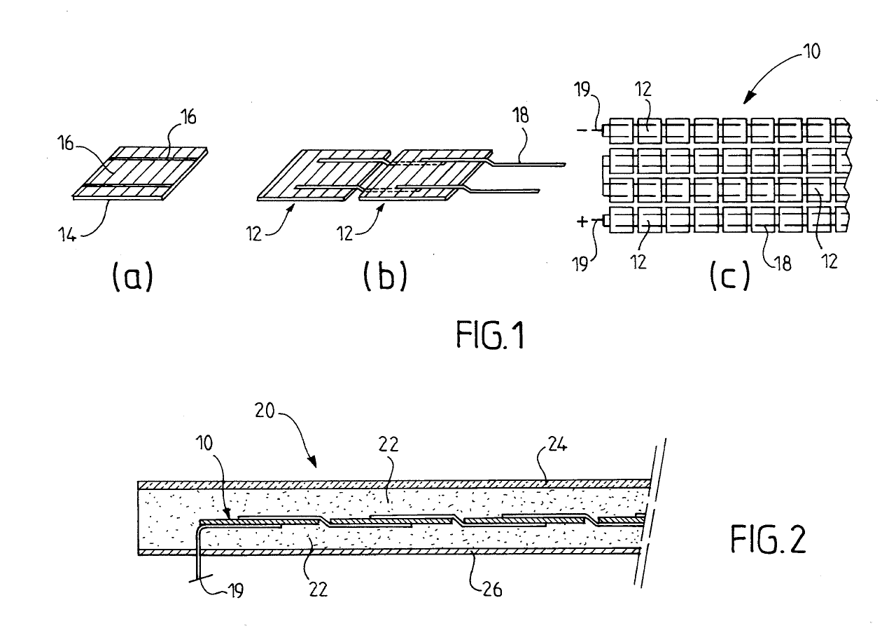

### DETAILED DESCRIPTION OF THE INVENTION

### Encapsulant:

Regarding firstly the encapsulant, it consists here of a layer which can be chosen from the aforementioned polyolefin or the aforementioned graft polymer. Thus, described below is firstly what is understood by the definition of the polyolefin then by the definition relating to the graft polymer.

Regarding therefore the polyolefin containing a polyethylene chosen from a homopolymer of ethylene or a copolymer comprising at least 50 mol % of ethylene and of one or more comonomers.

The following relate to the definition of one or more comonomers. Thus, regarding the comonomer, mention may be made of:
α-olefins, advantageously those having from 3 to 30 carbon atoms. These α-olefins may be used alone or as a mixture of two or more than two. As an α-olefin, mention may be made of ethylene, propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene. Preferably, the polyethylenes comprise one or more α-olefins comprising 3 to 8 carbons, with an ethylene content of greater than 50%. Ethylene/α-olefin copolymers are conventionally obtained by processes known to a person skilled in the art, such as for example by Ziegler-Natta, metallocene or organometallic polymerization as described in document WO 2008/036707. The density of these polymers measured according to the ASTM D 1505 standard may be from 0.860 to 0.96, advantageously from 0.860 to 0.920. Very preferably, the polyethylene is a linear low-density polyethylene (LLDPE);
unsaturated carboxylic acid esters such as, for example, alkyl acrylates or alkyl methacrylates grouped together under the term alkyl (meth)acrylates. The alkyl chains of these (meth)acrylates may have up to 30 carbon atoms. Mention may be made, as alkyl chains, of methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, heneicosyl, docosyl, tricosyl, tetracosyl, pentacosyl, hexacosyl, heptacosyl, octacosyl, nonacosyl. Methyl, ethyl and butyl (meth)acrylates are preferred as unsaturated carboxylic acid esters, the unsaturated carboxylic acid esters such as, for example, alkyl (meth)acrylates, it being possible for the alkyls to have up to 24 carbon atoms, examples of an alkyl acrylate or methacrylate are in particular methyl methacrylate, ethyl acrylate, n-butyl acrylate, isobutyl acrylate, 2-ethylhexyl acrylate. Ethylene/carboxylic acid ester copolymers are conventionally obtained by processes known to a person skilled in the art, such as for example the high-pressure autoclave or tubular process;
carboxylic acid vinyl esters. As examples of carboxylic acid vinyl esters, mention may be made of vinyl acetate, vinyl versatate, vinyl propionate, vinyl butyrate or vinyl maleate. Vinyl acetate is preferred as carboxylic acid vinyl ester;
dienes, such as for example 1,4-hexadiene.

The polyolefin may also comprise an additional functional monomer chosen from unsaturated carboxylic acid anhydrides, unsaturated dicarboxylic acid anhydrides, unsaturated carboxylic acids and unsaturated epoxides. As unsaturated monomers included in the polyolefin backbone, there are:
unsaturated epoxides are for example aliphatic glycidyl esters and ethers such as allyl glycidyl ether, vinyl glycidyl ether, glycidyl maleate and glycidyl itaconate, glycidyl acrylate and glycidyl methacrylate. They are also, for example, alicyclic glycidyl esters and ethers such as 2-cyclohexene-1-glycidyl ether, glycidyl cyclohexene-4,5-dicarboxylate, glycidyl cyclohexene-4-carboxylate, glycidyl 5-norbornene-2-methyl-2-carboxylate and diglycidyl endo-cis-bicyclo[2.2.1]-5-heptene-2,3-dicarboxylate. As unsaturated epoxide, glycidyl methacrylate is preferably used;
unsaturated carboxylic acids and their salts, for example acrylic acid or methacrylic acid and the salts of these same acids;
carboxylic acid anhydrides or dicarboxylic acid anhydrides may be chosen, for example, from maleic, itaconic, citraconic, allylsuccinic, cyclohex-4-ene-1,2-dicarboxylic, 4-methylenecyclohex-4-ene-1,2-dicarboxylic, bicyclo[2.2.1]hept-5-ene-2,3-dicarboxylic and x-methylbicyclo[2.2.1]hept-5-ene-2,2-dicarboxylic anhydrides. As anhydride, maleic anhydride is preferably used.

Regarding the aforementioned graft polymer (of the encapsulant), use will also preferably be made of 15% to 30% by weight of polyamide grafts and a number of monomers (X) between 1.3 in 10.

The flow temperature of the polyamide graft polymer is defined as the highest temperature among the melting temperatures and the glass transition temperatures of the polyamide grafts and of the polyolefin backbone. The backbone and the grafts are chosen so that the flow temperature of the polyamide graft polymer is greater than or equal to 75° C. and less than or equal to 160° C.

Regarding the polyolefin backbone relating to the skin part, it is a polymer comprising an α-olefin as monomer. Equally, what follows is also understood in connection with the core part of the encapsulant when the comonomer of the copolymer is an α-olefin.

α-Olefins having from 2 to 30 carbon atoms are preferred.

As α-olefin, mention may be made of ethylene, propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene.

Mention may also be made of cycloolefins having from 3 to 30 carbon atoms, preferably from 3 to 20 carbon atoms, such as cyclopentane, cycloheptene, norbornene, 5-methyl-2-norbornene, tetracyclododecene and 2-methyl-1,4,5,8-dimethano-1,2,3,4,4a,5,8,8a-octahydronaphthalene; diolefins and polyolefins, such as butadiene, isoprene, 4-methyl-1,3-pentadiene, 1,4-pentadiene, 1,5-hexadiene, 1,3-hexadiene, 1,3-octadiene, 1,4-octadiene, 1,5-octadiene, 1,6-octadiene, ethylidene norbornene, vinyl norbornene, dicyclopentadiene, 7-methyl-1,6-octadiene, 4-ethylidene-8-methyl-1,7-nonadiene and 5,9-dimethyl-1,4,8-decatriene; vinylaromatic compounds such as monoalkylstyrenes or polyalkylstyrenes (including styrene, o-methylstyrene, m-methylstyrene, p-methylstyrene, o,p-dimethylstyrene, o-ethylstyrene, m-ethylstyrene and p-ethylstyrene), and derivatives comprising functional groups such as methoxystyrene, ethoxystyrene, vinylbenzoic acid, vinylmethyl benzoate, vinylbenzyl acetate, hydroxystyrene, o-chlorostyrene, p-chlorostyrene, divinylbenzene, 3-phenylpropene, 4-phenylpropene, α-methylstyrene, vinyl chloride, 1,2-difluoroethylene, 1,2-dichloroethylene, tetrafluoroethylene and 3,3,3-trifluoro-1-propene.

Within the context of the present invention, the term “α-olefin” also comprises styrene. Propylene, and very especially ethylene, are preferred as α-olefin.

This polyolefin may be a homopolymer when a single α-olefin is polymerized in the polymer chain. Mention may be made, as examples, of polyethylene (PE) or polypropylene (PP).

This polyolefin may also be a copolymer when at least two comonomers are copolymerized in the polymer chain, one of the two comonomers referred to as the “first comonomer” being an α-olefin and the other comonomer, referred to as the “second comonomer”, is a monomer capable of polymerizing with the first monomer.

As the second comonomer, mention may be made of:
one of the α-olefins already mentioned, the latter being different from the first α-olefin comonomer,
dienes, such as for example 1,4-hexadiene, ethylidene norbornene and butadiene,
unsaturated carboxylic acid esters such as, for example, alkyl acrylates or alkyl methacrylates grouped together under the term alkyl (meth)acrylates. The alkyl chains of these (meth)acrylates may have up to 30 carbon atoms. Mention may be made, as alkyl chains, of methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, heneicosyl, docosyl, tricosyl, tetracosyl, pentacosyl, hexacosyl, heptacosyl, octacosyl, nonacosyl. Methyl, ethyl and butyl (meth)acrylates are preferred as unsaturated carboxylic acid esters,
carboxylic acid vinyl esters. As examples of carboxylic acid vinyl esters, mention may be made of vinyl acetate, vinyl versatate, vinyl propionate, vinyl butyrate or vinyl maleate. Vinyl acetate is preferred as carboxylic acid vinyl ester.

Advantageously, the polyolefin backbone comprises at least 50 mol % of the first comonomer; its density may advantageously be between 0.91 and 0.96.

The preferred polyolefin backbones consist of an ethylene/alkyl (meth)acrylate copolymer. By using this polyolefin backbone, excellent aging, light and temperature resistance are obtained.

It would not be outside of the scope of the invention if different “second comonomers” were copolymerized in the polyolefin backbone.

According to the present invention, the polyolefin backbone contains at least one residue of an unsaturated monomer (X) that can react at an acid and/or amine function of the polyamide graft via a condensation reaction. According to the definition of the invention, the unsaturated monomer (X) is not a “second comonomer”.

As unsaturated monomer (X) included in the polyolefin backbone, mention may be made of:
unsaturated epoxides. Among these are for example aliphatic glycidyl esters and ethers such as allyl glycidyl ether, vinyl glycidyl ether, glycidyl maleate and glycidyl itaconate, glycidyl acrylate and glycidyl methacrylate. They are also, for example, alicyclic glycidyl esters and ethers such as 2-cyclohexene-1-glycidyl ether, glycidyl cyclohexene-4,5-dicarboxylate, glycidyl cyclohexene-4-carboxylate, glycidyl 5-norbornene-2-methyl-2-carboxylate and diglycidyl endo-cis-bicyclo-[2.2.1]-5-heptene-2,3-dicarboxylate. As unsaturated epoxide, glycidyl methacrylate is preferably used;
unsaturated carboxylic acids and their salts, for example acrylic acid or methacrylic acid and the salts of these same acids;
carboxylic acid anhydrides. They may be chosen, for example, from maleic, itaconic, citraconic, allylsuccinic, cyclohex-4-ene-1,2-dicarboxylic, 4-methylenecyclohex-4-ene-1,2-dicarboxylic, bicyclo-[2.2.1]hept-5-ene-2,3-dicarboxylic and x-methylbicyclo[2.2.1]hept-5-ene-2,2-dicarboxylic anhydrides. As carboxylic acid anhydride, maleic anhydride is preferably used.

The unsaturated monomer (X) is preferably chosen from an unsaturated carboxylic acid anhydride and an unsaturated epoxide. In particular, for achieving the condensation of the polyamide graft with the polyolefin backbone, in the case where the reactive end group of the polyamide graft is a carboxylic acid function, the unsaturated monomer (X) is preferably an unsaturated epoxide. In the case where the reactive end group of the polyamide graft is an amine function, the unsaturated monomer (X) is advantageously an unsaturated epoxide and preferably an unsaturated carboxylic acid anhydride.

According to one advantageous version of the invention, the preferred number of unsaturated monomers (X) attached, on average, to the polyolefin backbone is greater than or equal to 1.3 and/or preferably less than or equal to 10.

Thus, when (X) is maleic anhydride and the number-average molar mass of the polyolefin is 15 000 g/mol, it was found that this corresponded to an anhydride proportion of at least 0.8%, and at most 6.5%, by weight of the whole of the polyolefin backbone. These values associated with the mass of the polyamide grafts determine the proportion of polyamide and of backbone in the polyamide graft polymer.

The polyolefin backbone containing the residue of the unsaturated monomer (X) is obtained by polymerization of the monomers (first comonomer, optional second comonomer, and optionally unsaturated monomer (X)). This polymerization can be carried out by a high-pressure radical process or a process in solution, in an autoclave or tubular reactor, these processes and reactors being well known to a person skilled in the art. When the unsaturated monomer (X) is not copolymerized in the polyolefin backbone, it is grafted to the polyolefin backbone. The grafting is also an operation that is known per se. The composition would be in accordance with the invention if several different functional monomers (X) were copolymerized with and/or grafted to the polyolefin backbone.

Depending on the types and ratio of monomers, the polyolefin backbone may be semicrystalline or amorphous. In the case of amorphous polyolefins, only the glass transition temperature is observed, whereas in the case of semicrystalline polyolefins a glass transition temperature and a melting temperature (which will inevitably be higher) are observed. A person skilled in the art will only have to select the ratios of monomer and the molecular masses of the polyolefin backbone in order to be able to easily obtain the desired values of the glass transition temperature, optionally of the melting temperature, and also of the viscosity of the polyolefin backbone.

Preferably, the polyolefin has a melt flow index (MFI) between 3 and 400 g/10 min (190° C., 2.16 kg, ASTM D 1238).

The polyamide grafts may be either homopolyamides or copolyamides.

The expression “polyamide grafts” especially targets the aliphatic homopolyamides which result from the polycondensation:
of a lactam;
or of an aliphatic α,ω-aminocarboxylic acid;
or of an aliphatic diamine and an aliphatic diacid.

As examples of a lactam, mention may be made of caprolactam, oenantholactam and lauryllactam.

As examples of an aliphatic α,ω-aminocarboxylic acid, mention may be made of aminocaproic acid, 7-aminoheptanoic acid, 11-aminoundecanoic acid and 12-aminododecanoic acid.

As examples of an aliphatic diamine, mention may be made of hexamethylenediamine, dodecamethylenediamine and trimethylhexamethylenediamine.

As examples of an aliphatic diacid, mention may be made of adipic, azelaic, suberic, sebacic and dodecanedicarboxylic acids.

Among the aliphatic homopolyamides, mention may be made, by way of example and nonlimitingly, of the following polyamides: polycaprolactam (PA-6); polyundecanamide (PA-11, sold by Arkema under the brand Rilsan®); polylauryllactam (PA-12, also sold by Arkema under the brand Rilsan®); polybutylene adipamide (PA-4,6); polyhexamethylene adipamide (PA-6,6); polyhexamethylene azelamide (PA-6,9); polyhexamethylene sebacamide (PA-6,10); polyhexamethylene dodecanamide (PA-6,12); polydecamethylene dodecanamide (PA-10,12); polydecamethylene sebacamide (PA-10,10) and polydodecamethylene dodecanamide (PA-12,12).

The expression “semicrystalline polyamides” also targets cycloaliphatic homopolyamides.

Mention may especially be made of the cycloaliphatic homopolyamides which result from the condensation of a cycloaliphatic diamine and an aliphatic diacid.

As an example of a cycloaliphatic diamine, mention may be made of 4,4′-methylenebis(cyclohexylamine), also known as para-bis(aminocyclohexyl)methane or PACM, 2,2′-dimethyl-4,4′-methylenebis(cyclohexylamine), also known as bis(3-methyl-4-aminocyclohexyl)methane or BMACM.

Thus, among the cycloaliphatic homopolyamides, mention may be made of the polyamides PACM,12 resulting from the condensation of PACM with the C12 diacid, BMACM,10 and BMACM,12 resulting from the condensation of BMACM with, respectively, C10 and C12 aliphatic diacids.

The expression “polyamide grafts” also targets the semiaromatic homopolyamides that result from the condensation:
of an aliphatic diamine and an aromatic diacid, such as terephthalic acid (T) and isophthalic acid (I). The polyamides obtained are then commonly known as “polyphthalamides” or PPAs; and
of an aromatic diamine, such as xylylenediamine, and more particularly meta-xylylenediamine (MXD) and an aliphatic diacid.

Thus, nonlimitingly, mention may be made of the polyamides 6,T, 6,I, MXD,6 or else MXD,10.

The polyamide grafts used in the composition according to the invention are preferably copolyamides. These result from the polycondensation of at least two of the groups of monomers mentioned above in order to obtain homopolyamides. The term “monomer” in the present description of the copolyamides should be taken in the sense of a “repeat unit”. This is because the case where a repeat unit of the PA is formed from the combination of a diacid with a diamine is particular. It is considered that it is the combination of a diamine and a diacid, that is to say the diamine-diacid pair (in an equimolar amount), which corresponds to the monomer. This is explained by the fact that individually, the diacid or the diamine is only one structural unit, which is not enough on its own to be polymerized in order to give a polyamide.

Thus, the copolyamides cover especially the condensation products of:
at least two lactams;
at least two aliphatic α,ω-aminocarboxylic acids;
at least one lactam and at least one aliphatic α,ω-aminocarboxylic acid;
at least two diamines and at least two diacids;
at least one lactam with at least one diamine and at least one diacid;
at least one aliphatic α,ω-aminocarboxylic acid with at least one diamine and at least one diacid,
   the diamine(s) and the diacid(s) possibly being, independently of one another, aliphatic, cycloaliphatic or aromatic.

Depending on the types and ratio of monomers, the copolyamides may be semicrystalline or amorphous. In the case of amorphous copolyamides, only the glass transition temperature is observed, whereas in the case of semicrystalline copolyamides a glass transition temperature and a melting temperature (which will inevitably be higher) are observed.

Among the amorphous copolyamides that can be used within the context of the invention, mention may be made, for example, of the copolyamides containing semiaromatic monomers.

Among the copolyamides, it is also possible to use semicrystalline copolyamides and particularly those of the PA-6/11, PA-6/12 and PA-6/11/12 type.

The degree of polymerization may vary to a large extent; depending on its value it is a polyamide or a polyamide oligomer.

Advantageously, the polyamide grafts are monofunctional.

So that the polyamide graft has a monoamine end group, it is sufficient to use a chain limiter of formula:

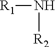

in which:
R1 is hydrogen or a linear or branched alkyl group containing up to 20 carbon atoms; and
R2 is a group having up to 20 carbon atoms that is a linear or branched alkyl or alkenyl group, a saturated or unsaturated cycloaliphatic radical, an aromatic radical or a combination of the preceding. The limiter may be, for example, laurylamine or oleylamine.

So that the polyamide graft has a carboxylic monoacid end group, it is sufficient to use a chain limiter of formula R′1-COOH, R′1-CO—O—CO—R′2 or a carboxylic diacid.

R′1 and R′2 are linear or branched alkyl groups containing up to 20 carbon atoms.

Advantageously, the polyamide graft has one end group having an amine functionality. The preferred monofunctional polymerization limiters are laurylamine and oleylamine.

Advantageously, the polyamide grafts have a molar mass between 1000 and 5000 g/mol and preferably between 2000 and 3000 g/mol.

The polycondensation defined above is carried out according to commonly known processes, for example at a temperature generally between 200° C. and 300° C., under vacuum or in an inert atmosphere, with stirring of the reaction mixture. The average chain length of the graft is determined by the initial molar ratio between the polycondensable monomer or the lactam and the monofunctional polymerization limiter. For the calculation of the average chain length, one chain limiter molecule is usually counted per one graft chain.

A person skilled in the art will only have to select the types and ratio of monomers and also choose the molar masses of the polyamide grafts in order to be able to easily obtain the desired values of the glass transition temperature, optionally of the melting temperature and also of the viscosity of the polyamide graft.

The condensation reaction of the polyamide graft on the polyolefin backbone containing the residue of (X) is carried out by reaction of one amine or acid function of the polyamide graft with the residue of (X). Advantageously, monoamine polyamide grafts are used and amide or imide bonds are created by reacting the amine function with the function of the residue of (X).

This condensation is preferably carried out in the melt state. To manufacture the composition according to the invention, it is possible to use conventional kneading and/or extrusion techniques. The components of the composition are thus blended to form a compound which may optionally be granulated on exiting the die. Advantageously, coupling agents are added during the compounding.

To obtain a nanostructured composition, it is thus possible to blend the polyamide graft and the backbone in an extruder, at a temperature generally between 200° C. and 300° C. The average residence time of the molten material in the extruder may be between 5 seconds and 5 minutes, and preferably between 20 seconds and 1 minute. The efficiency of this condensation reaction is evaluated by selective extraction of free polyamide grafts, that is to say those that have not reacted to form the polyamide graft polymer.

The preparation of polyamide grafts having an amine end group and also their addition to a polyolefin backbone containing the residue of (X) is described in U.S. Pat. No. 3,976,720, U.S. Pat. No. 3,963,799, U.S. Pat. No. 5,342,886 and FR 2291225.

The polyamide graft polymer of the present invention advantageously has a nanostructured organization. To obtain this type of organization, use will preferably be made, for example, of grafts having a number-average molar mass Mₙ between 1000 and 5000 g/mol and more preferably between 2000 and 3000 g/mol.

Plasticizers could be added to the layer forming the encapsulant in order to facilitate processing and improve the productivity of the process for manufacturing the composition and the structures. Mention will be made, as examples, of paraffinic, aromatic or naphthalenic mineral oils which also make it possible to improve the adhesive strength of the composition according to the invention. Mention may also be made, as plasticizers, of phthalates, azelates, adipates, and tricresyl phosphate.

Flame retardants could also be added. It is also possible to add coloring or whitening compounds.

In the same way, adhesion promoters, although not necessary, may advantageously be added in order to improve the adhesive strength of the composition when this adhesive strength must be particularly high. The adhesion promoter is a non-polymeric ingredient; it may be organic, crystalline, mineral and more preferably semi-mineral semi-organic. Among the latter, mention may be made of organic titanates or silanes, such as for example monoalkyl titanates, trichlorosilanes and trialkoxysilanes. Advantageously, use will be made of trialkoxysilanes containing an epoxy, vinyl and amine group in particular in the case where these adhesion promoters are provided as a masterbatch with the encapsulant-backsheet according to the invention. Provision may also be made for these adhesion promoters to be directly grafted to the polyolefin of the layer forming an encapsulant by a technique well known to those skilled in the art, for example reactive extrusion.

Since UV radiation is capable of resulting in a slight yellowing of the composition used as an encapsulant for said modules, UV stabilizers and UV absorbers, such as benzotriazole, benzophenone and other hindered amines, may be added in order to ensure the transparency of the encapsulant during its service life. These compounds may be, for example, based on benzophenone or benzotriazole. They can be added in amounts of less than 10%, and preferably of from 0.1% to 5%, by weight of the total weight of the composition.

Antioxidants could also be added in order to limit yellowing during the manufacture of the encapsulant, such as phosphorus-containing compounds (phosphonites and/or phosphites) and hindered phenolics. These antioxidants can be added in amounts of less than 10%, and preferably of from 0.1% to 5%, by weight of the total weight of the composition.

Similarly, flame retardants may also be added to the encapsulant layer and also to the layer forming the backsheet (described below). These agents may be halogenated or non-halogenated. Among the halogenated agents, mention may be made of brominated products. Use may also be made, as non-halogenated agent, of additives based on phosphorus such as ammonium phosphate, polyphosphate, phosphinate or pyrophosphate, melamine cyanurate, pentaerythritol, zeolites and also mixtures of these agents. The composition may comprise these agents in proportions ranging from 3% to 40% relative to the total weight of the composition.

It is also possible to add pigments, such as for example coloring or whitening compounds, to the encapsulant layer in proportions generally ranging from 5% to 15% relative to the total weight of the composition.

### Backsheet:

Regarding the main, or even sole, layer of the backsheet, this is a graft polymer substantially identical to that present in the encapsulant but having one essential difference.

Specifically, here, the flow temperature of the polyamide graft polymer is defined as the highest temperature among the melting temperatures and glass transition temperatures of the polyamide grafts and of the polyolefin backbone. The backbone and the grafts are chosen so that the flow temperature of the polyamide graft polymer is greater than 160° C.

Furthermore, use will also preferably be made of 15% to 50% by weight of polyamide grafts and a number of monomers (X) of between 1.3 and 10.

Apart from the elements for defining the graft polymer of the backsheet given above, the characteristics of the latter are absolutely identical to those of the graft polymer specific to the encapsulant so that, for the description of the graft polymer of the backsheet, reference is made here to the paragraphs of the graft polymer of the encapsulant.

According to one possibility offered by the invention, the backsheet will consist of a supplementary layer, adjacent to the aforementioned main layer formed by the graft polymer, consisting of a fluoropolymer such as, in particular, a homopolymer of vinylidene difluoride, a copolymer of vinylidene difluoride and at least one other fluoromonomer or heterogeneous vinylidene fluoride (VF₂)/fluoro comonomer copolymers.

This additional layer will furthermore be located without any contact with the encapsulant, that is to say on the side opposite the encapsulant, so that it will always be the graft polymer layer of the backsheet that will be in contact with the layer forming the encapsulant.

The fluoropolymer that is incorporated into the composition according to the invention is prepared:

1) either by polymerization of one or more monomer(s) of formula (I):

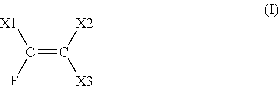

in which:
X₂ denotes H or F;
X₂ and X₃ denote H, F, Cl, a fluoroalkyl group of formula CₙFₘHₚ— or a fluoroalkoxy group CₙFₘHₚO—, n being an integer between 1 and 10, m being an integer between 1 and (2n+1) and p having the value 2n+1−m.

As examples of monomers, mention may be made of hexafluoropropylene (HFP), tetrafluoroethylene (TFE), vinylidene fluoride (VDF, CH₂═CF₂), chlorotrifluoroethylene (CTFE), perfluoroalkyl vinyl ethers, such as CF₃—O—CF═CF₂, CF₃—CF₂—O—CF═CF₂ or CF₃—CF₂CF₂—O—CF═CF₂, 1-hydropentafluoropropene, 2-hydropentafluoropropene, dichlorodifluoroethylene, trifluoroethylene (VF₃), 1,1-dichlorofluoroethylene and mixtures thereof, or fluorine-containing diolefins, for example diolefins such as perfluorodiallyl ether and perfluoro-1,3-butadiene.

As examples of fluoropolymers, mention may be made of:
TFE homopolymers or copolymers, in particular PTFE (polytetrafluoroethylene), ETFE (ethylene/tetrafluoroethylene copolymer) and TFE/PMVE (tetrafluoroethylene/perfluoro(methyl vinyl)ether copolymer), TFE/PEVE (tetrafluoroethylene/perfluoro(ethyl vinyl)ether copolymer), TFE/PPVE (tetrafluoroethylene/perfluoro(propyl vinyl)ether copolymer) and E/TFE/HFP (ethylene/tetrafluoroethylene/hexafluoropropylene terpolymers) copolymers;
VDF homopolymers or copolymers, in particular PVDF and VDF/HFP copolymers;
CTFE homopolymers or copolymers, in particular PCTFE (polychlorotrifluoroethylene) and E/CTFE (ethylene/chlorotrifluoroethylene copolymer).

Preferably, the fluoropolymer is a VDF homopolymer or copolymer.

Advantageously, the fluoro comonomer which can copolymerize with the VDF is chosen, for example, from vinyl fluoride, trifluoroethylene (VF₃); chlorotrifluoroethylene (CTFE); 1,2-difluoroethylene; tetrafluoroethylene (TFE); hexafluoropropylene (HFP); perfluoro(alkyl vinyl)ethers, such as perfluoro(methyl vinyl)ether (PMVE), perfluoro(ethyl vinyl)ether (PEVE) and perfluoro(propyl vinyl)ether (PPVE); perfluoro(1,3-dioxole); perfluoro(2,2-dimethyl-1,3-dioxole) (PDD), and mixtures thereof.

Preferably, the fluoro comonomer is chosen from chlorotrifluoroethylene (CTFE), hexafluoropropylene (HFP), trifluoroethylene (VF₃) and tetrafluoroethylene (TFE), and mixtures thereof. The comonomer is advantageously HFP as it copolymerizes well with VDF and makes it possible to contribute good thermomechanical properties. Preferably, the copolymer comprises only VDF and HFP.

Preferably, the fluoropolymer is a VDF homopolymer (PVDF) or a VDF copolymer, such as VDF/HFP, containing at least 50% by weight of VDF, advantageously at least 75% by weight of VDF and preferably at least 90% by weight of VDF. Mention may be made, for example, more particularly of the following VDF homopolymers or copolymers containing more than 75% of VDF and the remainder of HFP: Kynar® 710, Kynar® 720, Kynar® 740, Kynar Flex® 2850 and Kynar Flex® 3120, sold by Arkema.

Advantageously, the VDF homopolymer or copolymer has a viscosity ranging from 100 Pa·s to 3000 Pa·s, the viscosity being measured at 230° C. at a shear gradient of 100 s⁻¹ using a capillary rheometer. This is because this type of polymer is well suited to extrusion. Preferably, the polymer has a viscosity ranging from 500 Pa·s to 2900 Pa·s, the viscosity being measured at 230° C. at a shear gradient of 100 s⁻¹ using a capillary rheometer.

2) Or by polymerization of one or more monomers of formula (I) with one or more alkyl vinyl ether monomers of formula (II):

Formula (II): alkyl vinyl ether monomer: CH₂═CH(OR) where the R group is an aliphatic or cycloaliphatic alkyl group or a group of —R′OH type where R′ is an aliphatic alkyl group.

Among the fluoropolymers corresponding to this description, mention may be made of the copolymers of chlorotrifluoroethylene with one or more alkyl vinyl ether monomer(s) sold by Asahi Glass under the name Lumiflon®.

This type of fluoropolymer may be crosslinked via the reaction of the hydroxide of the alkyl vinyl ether monomer with a crosslinking agent. As examples of crosslinking agents, mention may be made of silanes, titanates and isocyanates. In order to promote the reaction between the crosslinking agent and the hydroxide group of the alkyl vinyl ether group, a catalyst may be added to the formulation. For example, in order to accelerate the reaction between the hydroxide groups of the fluoropolymer and an isocyanate crosslinking agent, tin-based catalysts, such as dibutyltin dilaurate, may be used.

In the case where the fluoropolymer comprises at least one pigment, a “filler” is present either in the form of an additional polymer which may be a homopolymer or copolymer of methyl methacrylate (MMA) or in the form of inorganic particles.

Regarding the MMA polymer, use is advantageously made of methyl methacrylate (MMA) homopolymers and copolymers containing at least 50% by weight of MMA and at least one other monomer which can copolymerize with MMA.

As examples of comonomers which can copolymerize with MMA, mention may be made, for example, of alkyl (meth)acrylates, acrylonitrile, butadiene, styrene or isoprene. Examples of alkyl (meth)acrylates are described in Kirk-Othmer Encyclopedia of Chemical Technology, 4^{th} edition (1991) in vol. 1, pages 292-293 and in vol. 16, pages 475-478.

Advantageously, the MMA polymer (homopolymer or copolymer) comprises, by weight, from 0 to 20% and preferably from 5% to 15% of a C₁-C₈ alkyl (meth)acrylate, which is preferably methyl acrylate and/or ethyl acrylate. The MMA polymer (homopolymer or copolymer) can be functionalized, that is to say that it contains, for example, acid, acid chloride, alcohol or anhydride functions. These functions may be introduced by grafting or by copolymerization. Advantageously, the functionality is in particular the acid function introduced by the acrylic acid comonomer. Use may also be made of a monomer comprising two neighbouring acrylic acid functions which can dehydrate to form an anhydride. The proportion of functionality can be from 0 to 15% by weight of the MMA polymer, for example from 0 to 10% by weight.

The MMA polymer may advantageously contain at least one impact modifier. There are commercial grades of MMA polymer that are said to be impact resistant, which contain an acrylic impact modifier in the form of multilayer particles. The impact modifier is then present in the MMA polymer as it is sold (that is to say introduced into the MMA resin during the manufacturing process) but it may also be added during the manufacture of the film. The amount of impact modifier varies from 0 to 30 parts per 70 to 100 parts of MMA polymer, the total making 100 parts.

Impact modifiers of the multilayer particle type, also commonly known as core-shell particles, comprise at least one elastomeric (or soft) layer, that is to say a layer formed from a polymer having a glass transition temperature (Tg) below −5° C. and at least one rigid (or hard) layer, that is say formed from a polymer having a Tg above 25° C. The size of the particles is generally less than 1 μm and advantageously between 50 and 300 nm. Examples of impact modifiers in the form of core-shell type multilayer particles will be found in the following documents: EP 1 061 100 A1, US 2004/0030046 A1, FR-A-2446296 or US 2005/0124761A1. Core-shell type particles that have at least 80 wt % of soft elastomeric phase are preferred.

The MVI (melt volume index) of the MMA polymer may be between 2 and 15 cm³/10 min, measured at 230° C. under a load of 3.8 kg.

The content of MMA polymer in the fluoropolymer composition is between 1 and 55 wt %, advantageously between 5 and 50 wt %, preferably between 10 and 45 wt % and more preferably still between 20 and 40 wt %.

Regarding the inorganic particles, it is possible to use a metal oxide such as for example titanium dioxide (TiO₂), silica, quartz, alumina, a carbonate such as, for example, calcium carbonate, talc, mica, dolomite (CaCO₃.MgCO₃), montmorillonite (aluminosilicate), BaSO₄, ZrSiO₄, Fe₃O₄, and mixtures thereof.

The mineral filler has an opacifying function in the UV/visible range. The protective action of the filler is complementary to that of the UV absorber. A TiO₂ filler is very particularly preferred from this point of view.

The mineral filler, for example of TiO₂ type, acts as solar filters, mainly by scattering/reflection of the UV rays, but also of the visible light, in order to have an opaque film.

The mineral filler may have another function. For example, it may have a flame retardant function, such as for example antimony oxide (Sb₂O₃, Sb₂O₅), Al(OH)₃, Mg(OH)₂, huntite (3MgCO₃.CaCO₃), hydromagnesite (3MgCO₃.Mg(OH)₂.3H₂O). It may also be an electrically conductive filler (for example, carbon black or else carbon nanotubes).

The filler has a size, expressed as the average diameter, that is generally between 0.05 μm and 1 mm, advantageously between 0.1 μm and 700 μm, preferably between 0.2 μm and 500 μm. The mineral filler content in the composition is between 0.1 and 30 wt %, advantageously between 5 and 28 wt %, preferably between 10 and 27 wt % and more preferably still between 15 and 25 wt %.

The backsheet, that is to say its first layer or main layer and its optional secondary layer, could advantageously comprise pigments such as, for example, titanium dioxide, zinc oxides or zinc sulfides. These pigments may make it possible to obtain better properties regarding the light reflection and a better opacity, which makes it possible to improve the amount of electricity that can be produced by the photovoltaic module.

All these additives may be added directly to the layers of the backsheet or be added in the form of a masterbatch.

Fillers, in particular mineral fillers, may be added in order to improve the thermomechanical resistance of the composition. Given nonlimitingly as examples are silica, alumina or calcium carbonates or carbon nanotubes or else glass fibers. Use may be made of modified or unmodified clays, which are mixed on the nanometer scale; this makes it possible to obtain a more transparent composition.

### Crosslinking/Preparation of the Encapsulant and of the Backsheet and Production of an Encapsulant-Backsheet Film According to the Invention (Intended to Form all or Part of a Photovoltaic Module):

Regarding the encapsulant, although crosslinking is not obligatory, it is possible in order to further improve the thermomechanical properties of the encapsulant, in particular when the temperature becomes very high. It would not therefore be outside of the scope of the invention if crosslinking agents are added. As examples, mention may be made of isocyanates or organic peroxides. This crosslinking may also be carried out by known irradiation techniques. This crosslinking may be carried out by one of many methods known to a person skilled in the art, in particular by the use of thermally-activated initiators, for example peroxides and azo compounds, photoinitiators such as benzophenone, by radiation techniques comprising light rays, UV rays, electron beams and X-rays, silanes bearing reactive functions such as an aminosilane, an epoxysilane, a vinylsilane such as for example vinyltriethoxysilane or vinyltrimethoxysilane, and moisture crosslinking. The manual entitled “Handbook of Polymer Foams and Technology” above, on pages 198 to 204, provides additional information to which a person skilled in the art may refer.

The multilayer structure according to invention may be obtained by conventional techniques for producing films, sheets or slabs. As examples, mention may be made of the techniques of blown-film extrusion, extrusion-lamination, extrusion-coating, cast-film extrusion, or else sheet extrusion. All these techniques are known to those skilled in the art and they will know how to adapt the processing conditions of the various techniques (temperature of the extruders, connector, dies and feedblock, rotational speed of the screws, cooling temperatures of the cooling rolls, etc.) in order to form the structure according to invention having the desired shape and the desired thicknesses. It would not be outside of the invention if the final structure was obtained by pressing techniques or lamination techniques with adhesives in a solvent or aqueous medium, or if the final structure was subjected to a supplementary postcuring step.

In the specific case of the multilayer structure according to invention comprising, in addition, a layer of fluoropolymer (combined with the Apolhya layer forming the backsheet), the latter is obtained by coextrusion, it being possible for a coextrusion polymer adhesive (also referred to as a “tie layer”) to be used in order to ensure good adhesion between the fluoro layer and the Apolhya layer. As examples, these adhesives will be chosen in order to develop the adhesion to the fluoro layer, such as fluoropolymers comprising an additional monomer of maleic anhydride (MAH) type (obtained by reactive extrusion grafting), acrylic polymers that are functionalized (acid or anhydride) or unfunctionalized, thermoplastic polyurethanes (TPUs), etc. It would not be outside of the invention if several successive adhesive layers were used. Thus, preferably, the structure will comprise two successive adhesive layers between the fluoro layer and the apolhya layer, the adhesives used possibly consisting of:
a first adhesive chosen from MAH-grafted PVDFs, acrylics (PMMA, etc.) or an acrylic polymer/PVDF blend,
a second adhesive consisting of an ethylene/epoxy copolymer or terpolymer (Lotader glycidyl methacrylate (GMA)).

Finally, in the specific case of the multilayer structure comprising an additional layer of fluoropolymer, it would not be outside of the invention if the fluoro layer was deposited by coating in an aqueous or solvent medium (a person skilled in the art can refer, for further details, to document WO 2010/144520).

Regarding the aspects of the invention relating to the use of the thermoplastic composition in a photovoltaic module, a person skilled in the art may refer, for example, to the Handbook of Photovoltaic Science and Engineering, Wiley, 2003. Specifically, the composition of the invention can be used as an encapsulant or encapsulant-backsheet in a photovoltaic module, the structure of which is described in connection with the appended figures.

### Materials Used for Forming the Formulations Tested:

### Apolhya Solar® LC3UV:

The Apolhya Solar® family is a family of polymers sold by ARKEMA which combine the properties of polyamides with those of polyolefins owing to co-continuous morphologies being obtained on the nanometer scale. Within the context of the tests, Apolhya Solar® LC3UV is used here, which is one of the grades of the Apolhya Solar® family which is characterized by an MFI (Melt Flow Index) of 10 grams/10 minutes at 230° C. under 2.16 kg, sold by the applicant. This product has an elastic modulus of 65 MPa at ambient temperature and a melting point of 130° C.

### Apolhya® LP92:

The Apolhya® family is a family of polymers sold by ARKEMA which combine the properties of polyamides with those of polyolefins owing to co-continuous morphologies being obtained on the nanometer scale. Within the context of the tests, Apolhya® LP92 is used here, which is one of the grades of the Apolhya® family suitable for use as a backsheet. This grade is characterized by an MFI (Melt Flow Index) of 0.5 grams/10 minutes at 230° C. under 2.16 kg (AE) and a melting point of 220° C.

### Akasol® PVL 1000V:

Fluoro backsheet sold by Krempel. This film consists of a PET core layer and two PVDF outer layers. In order to promote adhesion between the backsheet and the encapsulant, the face of the Akasol® intended to be in contact with the encapsulant was subjected to a corona surface treatment.

### Obtaining the Formulations and Films Tested:

Single-layer films of 400 μm and double-layer films of 800 μm were produced by cast-film extrusion on a Dr COLLIN brand extrusion line. This extrusion line is composed of three extruders equipped with a standard polyolefin screw profile, a variable coextrusion block (variable feedblock), and a 250 mm coat hanger die. The coextrusion block allows the production of a film having two layers (layer 1/layer 2) with a variable distribution of thicknesses.

In the case of the 400 μm single-layer film of Apolhya Solar® LC3UV, the following process parameters were set:
extrusion temp: 150° C. (degrees Celsius);
coextrusion box and die temp: 160° C.;
line speed is 2.6 m/min (meters per minute).

In the case of the 400 μm single-layer film of Apolhya®LP92, the following process parameters were set:
extrusion temp: 220-240° C.;
coextrusion box and die temp: 240° C.;
line speed is 2.6 m/min.

In the case of the 800 μm double-layer LC3UV/LP92 film, the following production/manufacturing parameters were set:
extrusion temp of Apolhya Solar® LC3UV layer: 150° C.;
extrusion temp of Apolhya® LP92 layer: 200-220° C.;
coextrusion box and die temp: 220° C.;
line speed is 2.6 m/min.

### Tests Carried Out on the Films:

### Assembly of Mini Test Modules

Mini test modules were assembled using a laboratory laminator from the company Penergy. Two types of mini test modules were produced. The first type consists in successively stacking, on a 3 mm glass layer, a 400 μm LC3UV layer, a fragment of active layer made of crystalline silicon and the metallic connectors, a second LC3UV layer and finally an LP92 backsheet layer. The second type consists in successively stacking, on a 3 mm glass layer, a 400 μm LC3UV layer, a fragment of active layer made of crystalline silicon and the metallic connectors and finally the LC3UV/LP92 backsheet-encapsulant layer.

For the two types of structure, the lamination cycle applied is the following:
first step: degassing at 150° C. for 300 seconds;
second step: pressing at 150° C. for 160 seconds.

The quality of the modules is evaluated through the number of defects visible to the naked eye such as creases, bubbles, blisters, breakages of connectors, etc.

It will be noted that the film according to the invention is defined at the least by the combination of an encapsulant layer and a backsheet layer as defined previously. The advantage of the invention, defined as double-layer films having a single component in each of said layers, is demonstrated regarding the combination of compositions forming, on the one hand, the encapsulant and, on the other hand, the backsheet, but it is clearly understood that the intrinsic qualities of this film according to the invention could be substantially improved, in particular by the addition of a PVDF layer to the layer forming the backsheet and/or by the addition of additives having a specific functionality.

In the same manner, the film examples according to the invention all have the same thicknesses regarding the skin layer and core layer but it is clearly understood that a person skilled in the art could vary them as a function of the application of the photovoltaic module and of the performances of the latter with regard to the intrinsic properties of the encapsulant and of the backsheet, notwithstanding the synergy produced between the elements forming, on the one hand, the encapsulant and, on the other hand, the backsheet.

The present invention is illustrated in greater detail by the following nonlimiting examples.

### Example 1

Mini test module obtained by assembling, using a laminator, a stack of a glass layer, an LC3UV layer, a layer of crystalline silicon active cells, and a LC3UV/LP92 double-layer film layer.

### Comparative Example 1

Mini test module obtained by assembling, using a laminator, a stack of a glass layer, an LC3UV layer, a layer of crystalline silicon active cells, a single-layer LC3UV film and an Akasol® PVL 1000V backsheet.

### Results of the Tests Carried Out:

| | | Presence of glass or |
|---|---|---|
| | Presence of zones of | silicon zones not |
| | insufficient thickness | covered by the |
| | of the encapsulant | encapsulant |
| Example 1 | 0/10 | 0/10 |
| Comparative | 9/10 | 7/10 |
| example 1 | | |

1. A double-layer thermoplastic film for a photovoltaic module, comprising two layers, of which one layer forms the encapsulant and the other layer forms the backsheet, the film having a thickness of greater than 100 μm (micrometer), wherein:
a) the encapsulant consists of a layer comprising:
from 0% to 100% of one or more polyolefins containing a polyethylene chosen from a homopolymer of ethylene or a copolymer comprising at least 50 mol % of ethylene and of one or more comonomers,
from 0% to 100% of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end group and/or at least one carboxylic acid end group,
the residue of the unsaturated monomer (X) is attached to the backbone by grafting or copolymerization,
the polyolefin backbone and the polyamide graft being chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone;
b) the backsheet comprises a layer formed from a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end group and/or at least one carboxylic acid end group,
the residue of the unsaturated monomer (X) is attached to the backbone by grafting or copolymerization,
the polyolefin backbone and the polyamide graft being chosen so that said polyamide graft polymer has a flow temperature of greater than 160° C., this flow temperature being defined as the highest temperature among the melting temperatures and glass transition temperatures of the polyamide graft and of the polyolefin backbone.

2. The film as claimed in claim 1, wherein the aforesaid graft polymers of the encapsulant and of the backsheet are nanostructured.

3. The film as claimed in claim 1, wherein the number-average molar mass of the aforesaid polyamide grafts of the aforesaid graft polymers of the encapsulant and of the backsheet is within the range extending from 1000 to 5000 g/mol.

4. The film as claimed in claim 1, wherein, for the aforesaid graft polymers of the encapsulant and of the backsheet, the number of monomers (X) attached to the polyolefin backbone is greater than or equal to 1.3 and/or less than or equal to 10.

5. The film as claimed in claim 1, wherein the at least one polyamide graft of the graft polymer of the encapsulant comprises at least one copolyamide.

6. The film as claimed in claim 1, wherein the polyolefin backbone of the graft polymer of the encapsulant does not have a melting temperature or has a melting temperature below 110° C.

7. The film as claimed in claim 1, wherein the homopolymer of ethylene of the polyolefin of the encapsulant is a linear low-density polyethylene (LLDPE).

8. The film as claimed in claim 1, wherein the copolymer of polyethylene of the polyolefin of the encapsulant is chosen from an ethylene/α-olefin copolymer, the density of which is between 0.865 and 0.91 (ASTM D 1505 standard), or an ethylene/alkyl (meth)acrylates/anhydride copolymer.

9. The film as claimed in claim 1, wherein the backsheet also comprises a layer formed from a fluoropolymer consisting of a homopolymer of vinylidene difluoride or a copolymer of vinylidene difluoride and at least one other fluoromonomer.

10. The film as claimed in claim 1, wherein the layer forming a backsheet comprises fillers chosen from silica, alumina, calcium carbonates, carbon nanotubes, glass fibers or else modified or unmodified clays, which are mixed on the nanometer scale.

11. The film as claimed in claim 1, wherein the layer forming an encapsulant comprises adhesion promoters consisting of a non-polymeric ingredient, of organic, crystalline or mineral nature.

12. The film as claimed in claim 9, wherein the backsheet consists of two layers only and the encapsulant consists of a single layer.

13. A photovoltaic module comprising the film as claimed in claim 1.

14. A photovoltaic module having at least one layer forming an encapsulant comprising:
a photovoltaic cell capable of generating electrical energy and one layer forming a backsheet, these two layers constituting the film as claimed in claim 1.

15. The film as claimed in claim 1, wherein the number-average molar mass of the aforesaid polyamide grafts of the aforesaid graft polymers of the encapsulant and of the backsheet is within the range extending from 2000 to 3000 g/mol.

16. The film as claimed in claim 7, wherein the linear low-density polyethylene (LLDPE) is obtained by metallocene catalysis.
